(19) United States
(12) Patent Application Publication
(10) Pub. No.: US 2025/0070087 A1
(43) Pub. Date: Feb. 27, 2025

(54) SEMICONDUCTOR PACKAGE AND METHOD OF FABRICATING THE SAME

(71) Applicant: Samsung Electronics Co., Ltd., Suwon-si (KR)

(72) Inventor: Joo-Young Oh, Suwon-si (KR)

(21) Appl. No.: 18/613,540

(22) Filed: Mar. 22, 2024

(30) Foreign Application Priority Data
Aug. 21, 2023 (KR) 10-2023-0109003
Oct. 12, 2023 (KR) 10-2023-0136032

(51) Int. Cl. H01L 25/065; H01L 23/00; H01L 23/31

(52) U.S. Cl. CPC H01L 25/0657; H01L 23/3128; H01L 24/29; H01L 24/32; H01L 24/48; H01L 24/73; H01L 2224/29005; H01L 2224/32145; H01L 2224/32225; H01L 2224/48149; H01L 2224/48229; H01L 2224/73265; H01L 2225/06506; H01L 2225/0651; H01L 2225/06562; H01L 2924/1436; H01L 2924/1438

(57) ABSTRACT

A semiconductor package comprises a package substrate and a first chip stack. The first chip stack includes: a first semiconductor chip on the package substrate, a plurality of second semiconductor chips that are on the first semiconductor chip and have an offset stack structure, and a plurality of first adhesive layers that are respectively on a bottom surface of the first semiconductor chip and bottom surfaces of the second semiconductor chips. The first semiconductor chip includes: a first semiconductor substrate, a plurality of first integrated elements on a top surface of the first semiconductor substrate, and a first wiring layer on the top surface of the first semiconductor substrate. A width of the first semiconductor chip and a width of a lowermost one of the second semiconductor chips are the same. The first semiconductor chip is electrically insulated from the package substrate and the second semiconductor chips.

### CROSS-REFERENCE TO RELATED APPLICATIONS

This U.S. nonprovisional application claims priority under 35 U.S.C. § 119 to Korean Patent Application No. 10-2023-0109003 filed on Aug. 21, 2023 and Korean Patent Application No. 10-2023-0136032 filed on Oct. 12, 2003 in the Korean Intellectual Property Office, the disclosures of which are hereby incorporated by reference in their entirety.

### TECHNICAL FIELD

The present disclosure relate to a semiconductor package and a method of fabricating the same, and more particularly, to a semiconductor package including stacked semiconductor chips and a method of fabricating the same.

### BACKGROUND

A typical stacked package has a structure in which a plurality of devices are stacked. For example, the stacked package may include semiconductor chips that are sequentially stacked on a printed circuit board (PCB). Connection pads are formed on the semiconductor chips. As the connection pads are connected through bonding wires, the semiconductor chips may be electrically connected to a printed circuit board. The printed circuit board is provided thereon with a logic chip that controls the semiconductor chips.

Portable devices have been increasingly demanded in recent electronic product markets, and as a result, a reduction in size and weight of electronic parts mounted on the portable devices has been desired. In order to accomplish the reduction in size and weight of the electronic parts, a technology to integrate a number of individual devices into a single package as well as technology to reduce individual sizes of mounting parts may be desired. In particular, an increase in integration of a plurality of devices may cause the semiconductor package to have a reduced size, improved structural characteristics, and enhanced electrical properties.

### SUMMARY

Some embodiments of the present disclosure provide a semiconductor package with increased structural stability and a method of fabricating the same.

Some embodiments of the present disclosure provide a semiconductor package whose fabrication process is simplified and a method of fabricating the same.

According to some embodiments of the present disclosure, a semiconductor package may comprise: a package substrate, and a first chip stack on the package substrate, where the first chip stack includes: a first semiconductor chip on the package substrate, a plurality of second semiconductor chips that are on the first semiconductor chip and have an offset stack structure, and a plurality of first adhesive layers that are respectively on a bottom surface of the first semiconductor chip and bottom surfaces of the second semiconductor chips, where the first semiconductor chip includes: a first semiconductor substrate, a plurality of first integrated elements on a top surface of the first semiconductor substrate, and a first wiring layer on the top surface of the first semiconductor substrate, where a width of the first semiconductor chip and a width of a lowermost one of the second semiconductor chips are the same, and where the first semiconductor chip is electrically insulated from the package substrate and the second semiconductor chips.

According to some embodiments of the present disclosure, a semiconductor package may comprise: a package substrate, a first chip stack on the package substrate and including a plurality of first semiconductor chips that have an offset stack structure, a second semiconductor chip between the package substrate and the first chip stack, a plurality of bonding wires that electrically connect the first semiconductor chips to the package substrate, a molding layer that is on the package substrate, the second semiconductor chip, and the first chip stack, and a plurality of external terminals on a bottom surface of the package substrate, where the first semiconductor chips and the second semiconductor chip are a same type, where the second semiconductor chip is vertically aligned with a lowermost one of the first semiconductor chips, and where each thickness of the first semiconductor chips is the same as a thickness of the second semiconductor chip.

According to some embodiments of the present disclosure, a semiconductor package may comprise: a package substrate, and a first chip stack on the package substrate, where the first chip stack includes: a first semiconductor chip on the package substrate, a plurality of second semiconductor chips that are on the first semiconductor chip and have an offset stack structure, and a plurality of first adhesive layers that are respectively on a bottom surface of the first semiconductor chip and bottom surfaces of the second semiconductor chips, where the first semiconductor chip includes: a first semiconductor substrate, a plurality of first integrated elements on a top surface of the first semiconductor substrate, and a first wiring layer on the top surface of the first semiconductor substrate, where a width of the first semiconductor chip and a width of a lowermost one of the second semiconductor chips are the same, where a planar area of the first semiconductor chip and a planar area of the lowermost one of the second semiconductor chips are the same, where a thickness of the first semiconductor chip and a thickness of the lowermost one of the second semiconductor chips are the same, where a thickness of each of the plurality of first adhesive layers is the same, and where the first semiconductor chip is electrically insulated from the package substrate and the second semiconductor chips.

According to some embodiments of the present disclosure, a method of fabricating a semiconductor package may comprise: forming a plurality of semiconductor chips on a semiconductor wafer; testing the semiconductor chips; using a first adhesive layer to attach a first one of the semiconductor chips to a package substrate; using a plurality of second adhesive layers to stack second ones of the semiconductor chips on the first semiconductor chip, the second semiconductor chips being stacked in an offset stack structure; curing the first adhesive layer and the second adhesive layers; and forming a plurality of bonding wires that connect the second semiconductor chips to the package substrate. The first semiconductor chip and the second semiconductor chips may be of the same type. The first semiconductor chip may be a defective semiconductor chip determined as defective in a test process. The second semiconductor chips may be a normal semiconductor chip determined as normal in the test process.

### BRIEF DESCRIPTION OF DRAWINGS

FIG. 1 illustrates a cross-sectional view showing a semiconductor package according to some embodiments of the present disclosure.

FIG. 2 illustrates an enlarged view showing section A of FIG. 1.

FIG. 3 illustrates a cross-sectional view showing a semiconductor package according to some embodiments of the present disclosure.

FIG. 4 illustrates an enlarged view showing section B of FIG. 3.

FIG. 5 illustrates a cross-sectional view showing a semiconductor package according to some embodiments of the present disclosure.

FIG. 6 illustrates an enlarged view showing section C of FIG. 5.

FIGS. 7, 8, and 9 illustrate cross-sectional views showing a semiconductor package according to some embodiments of the present disclosure.

FIGS. 10 and 11 illustrate plan views showing a semiconductor wafer in a method of fabricating a semiconductor package according to some embodiments of the present disclosure.

FIGS. 12, 13, 14, 15, 16, 17, 18, and 19 illustrate cross-sectional views showing a method of fabricating a semiconductor package according to some embodiments of the present disclosure.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

The following will now describe a semiconductor package according to the present disclosure with reference to the accompanying drawings.

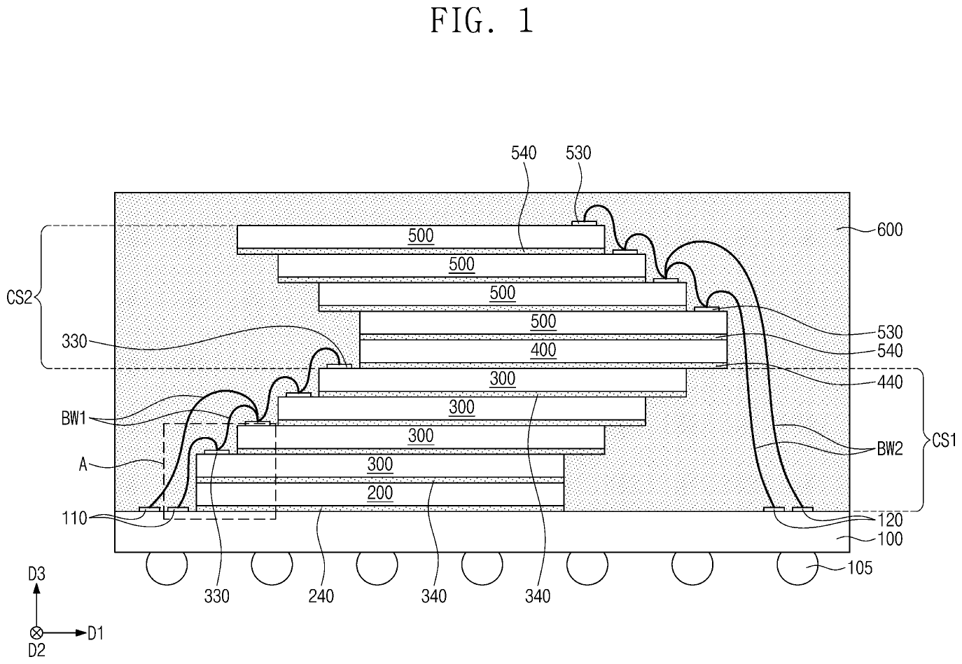

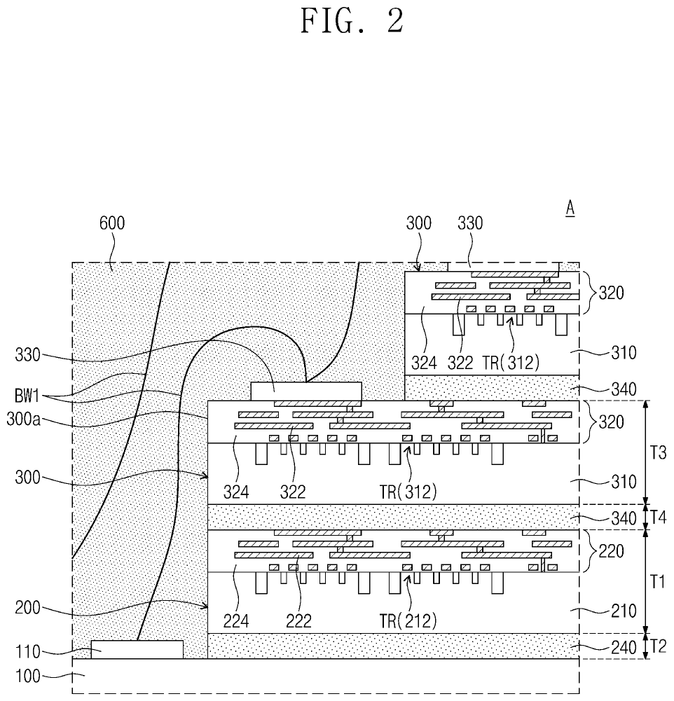

FIG. 1 illustrates a cross-sectional view showing a semiconductor package according to some embodiments of the present disclosure. FIG. 2 illustrates an enlarged view showing section A of FIG. 1.

Referring to FIGS. 1 and 2, a package substrate 100 may be provided. The package substrate 100 may be a printed circuit board (PCB) having a signal pattern provided on a top surface of the package substrate 100. The signal pattern may include signal pads 110 and 120. The package substrate 100 may have a structure in which at least one dielectric pattern and at least one wire pattern are alternately stacked. The package substrate 100 may have external terminals 105 provided on a bottom surface thereof. The external terminals 105 may include a solder ball, a solder bump, or a solder pad. Based on type of the external terminals 105, the package substrate 100 may have a ball grid array (BGA) type, a fine ball-grid array (FBGA) type, or a land grid array (LGA) type.

A first chip stack CS1 may be provided on the package substrate 100. The first chip stack CS1 may include a first semiconductor chip 200 and second semiconductor chips 300 that are stacked in a third direction D3 on the package substrate 100. In this description, a first direction D1 and a second direction D2 are defined to indicate directions that are parallel to the top surface of the package substrate 100 and intersect each other, and the third direction D3 is defined to indicate a direction perpendicular to the top surface of the package substrate 100. The first semiconductor chip 200 and the second semiconductor chips 300 may be a memory chip. For example, the first semiconductor chip 200 and the second semiconductor chips 300 may include a dynamic random access memory (DRAM) or a NAND Flash memory. For convenience of description in this disclosure, the first semiconductor chip 200 and the second semiconductor chips 300 are distinguished from each other, but the first semiconductor chip 200 and the second semiconductor chips 300 may be the same semiconductor chip.

The first semiconductor chip 200 may be disposed on the package substrate 100. The first semiconductor chip 200 may include an integrated element therein. For example, the first semiconductor chip 200 may be a wafer-level die formed of a semiconductor, such as silicon (Si). The first semiconductor chip 200 may have a front surface and a rear surface. In the following disclosure, the term “front surface” may be defined to indicate an active surface of an integrated element in a semiconductor chip, a surface on which wiring lines are formed, or a surface on which pads of a semiconductor chip are formed, and the term “rear surface” may be defined to indicate a surface opposite to the front surface. The rear surface of the first semiconductor chip 200 may be directed toward the package substrate 100. For example, the first semiconductor chip 200 may be disposed in a face-up state on the package substrate 100. The first semiconductor chip 200 may have a first thickness T1 of about 30 micrometers to about 100 micrometers.

The first semiconductor chip 200 may include a first semiconductor substrate 210 and a first wiring layer 220.

The first semiconductor substrate 210 may include a semiconductor material. For example, the first semiconductor substrate 210 may be a silicon (Si) monocrystalline substrate. The first semiconductor substrate 210 may have a top surface and a bottom surface that are opposite to each other. The top surface of the first semiconductor substrate 210 may be a front surface of the first semiconductor substrate 210, and the bottom surface of the first semiconductor substrate 210 may be a rear surface of the first semiconductor substrate 210. In this disclosure, the front surface of the first semiconductor substrate 210 may be defined to indicate a surface on which semiconductor devices are formed or mounted in the first semiconductor substrate 210 or on which wiring lines and pads are formed in the first semiconductor substrate 210, and the rear surface of the first semiconductor substrate 210 may be defined to indicate a surface opposite to the front surface. For example, the top surface of the first semiconductor substrate 210 may be an active surface.

First integrated elements 212 may be provided on the top surface of the first semiconductor substrate 210. The first integrated elements 212 may include transistors TR provided on the top surface of the first semiconductor substrate 210. For example, the transistors TR may each include a source and a drain that are formed on an upper portion of the first semiconductor substrate 210, a gate electrode disposed on the top surface of the first semiconductor substrate 210, and a gate dielectric layer interposed between the first semiconductor substrate 210 and the gate electrode. The first integrated elements 212 may include a memory circuit or a logic circuit. Although not shown, the first integrated elements 212 may include a device isolation pattern, a logic cell, or a plurality of memory cells disposed on the top surface of the first semiconductor substrate 210. In some embodiments, the first integrated elements 212 may include a passive element such as a capacitor.

The first wiring layer 220 may be provided on the top surface of the first semiconductor substrate 210. The first wiring layer 220 may include a first device wiring part 222 and a first device interlayer dielectric layer 224.

The top surface of the first semiconductor substrate 210 may be covered or overlapped with the first device interlayer dielectric layer 224. The first device interlayer dielectric layer 224 may bury or at least partially surround the first integrated elements 212. For example, the first integrated elements 212 may not be exposed by the first device interlayer dielectric layer 224. The first device interlayer dielectric layer 224 may include, for example, at least one selected from silicon oxide (SiO), silicon nitride (SiN), and silicon oxynitride (SiON). In some embodiments, the first device interlayer dielectric layer 224 may include a low-k dielectric material. The first device interlayer dielectric layer 224 may have a mono-layered structure or a multi-layered structure. When the first device interlayer dielectric layer 224 is provided as the multi-layered structure, an etch stop layer may be interposed between the dielectric layers. For example, the etch stop layer may be provided on a bottom surface of each dielectric layer. The etch stop layer may include, for example, one of silicon nitride (SiN), silicon oxynitride (SiON), and silicon carbonitride (SiCN).

The first device interlayer dielectric layer 224 may be provided therein with a first device wiring part 222 connected to the transistors TR. The first device wiring part 222 may include wiring patterns buried in or at least partially surrounded by the first device interlayer dielectric layer 224. For example, the wiring patterns may include redistribution patterns for horizontal wiring and via patterns for vertical connection. The first device wiring part 222 may vertically penetrate or extend into the first device interlayer dielectric layer 224 to connect to one of a source electrode, a drain electrode, and a gate electrode of the transistor TR. In some embodiments, the first device wiring part 222 may be connected to various components of the first integrated elements 212. The first device wiring part 222 may be positioned between top and bottom surfaces of the first device interlayer dielectric layer 224. A portion of the first device wiring part 222 may be exposed on the top surface of the first device interlayer dielectric layer 224. The first device wiring part 222 may include, for example, copper (Cu) or tungsten (W).

A first adhesive layer 240 may be provided on a bottom surface of the first semiconductor chip 200. The first semiconductor chip 200 may be attached through the first adhesive layer 240 to the package substrate 100. The first adhesive layer 240 may have a second thickness T2 of about 5 micrometers to about 20 micrometers. The first adhesive layer 240 may include a die attach film (DAF).

The first semiconductor chip 200 may be electrically insulated from the package substrate 100. For example, the first semiconductor chip 200 may not have any of connection terminals, connection wires, and connection structures that are separately provided for electrical connection between the first semiconductor chip 200 and the package substrate 100.

The second semiconductor chips 300 may be disposed on the first semiconductor chip 200. The second semiconductor chips 300 may include an integrated element therein. For example, the second semiconductor chips 300 may be wafer-level dies formed of a semiconductor, such as silicon (Si). The second semiconductor chips 300 may each have front surface and a rear surface. The rear surfaces of the second semiconductor chips 300 may be directed toward the first semiconductor chip 200. For example, the second semiconductor chips 300 may be face-up disposed on the first semiconductor chip 200. The second semiconductor chips 300 may each have a third thickness T3 of about 30 micrometers to about 100 micrometers. As discussed above, each of the second semiconductor chips 300 may be of the same type as the first semiconductor chip 200. For example, a configuration of each of the second semiconductor chips 300 may be substantially the same as that of the first semiconductor chip 200. A planar shape of each of the second semiconductor chips 300 may be the same as that of the first semiconductor chip 200. Each of the second semiconductor chips 300 may have a width the same as that of the first semiconductor chip 200. Each of the second semiconductor chips 300 may have a planar area the same as that of the first semiconductor chip 200. The third thickness T3 of the second semiconductor chips 300 may be the same as the first thickness T1 of the first semiconductor chip 200. The following will describe in detail a configuration of one second semiconductor chip 300.

The second semiconductor chip 300 may include a second semiconductor substrate 310 and a second wiring layer 320.

The second semiconductor substrate may include a semiconductor material. For example, the second semiconductor substrate 310 may be a silicon (Si) monocrystalline substrate. The second semiconductor substrate 310 may have a top surface and a bottom surface that are opposite to each other. The top surface of the second semiconductor substrate 310 may be a front surface of the second semiconductor substrate 310, and the bottom surface of the second semiconductor substrate 310 may be a rear surface of the second semiconductor substrate 310. For example, the top surface of the second semiconductor substrate 310 may be an active surface.

Second integrated elements 312 may be provided on the top surface of the second semiconductor substrate 310. The second integrated elements 312 may include transistors TR provided on the top surface of the second semiconductor substrate 310. For example, the transistors TR may each include a source and a drain that are formed on an upper portion of the second semiconductor substrate 310, a gate electrode disposed on the top surface of the second semiconductor substrate 310, and a gate dielectric layer interposed between the second semiconductor substrate 310 and the gate electrode. The second integrated elements 312 may include a memory circuit or a logic circuit. Although not shown, the second integrated elements 312 may include a device isolation pattern, a logic cell, or a plurality of memory cells disposed on the top surface of the second semiconductor substrate 310. In some embodiments, the second integrated elements 312 may include a passive element such as a capacitor. The second integrated elements 312 and the first integrated elements 212 may include the same integrated elements.

The second wiring layer 320 may be provided on the top surface of the second semiconductor substrate 310. The second wiring layer 320 may include a second device wiring part 322 and a second device interlayer dielectric layer 324.

The top surface of the second semiconductor substrate 310 may be covered or overlapped with the second device interlayer dielectric layer 324. The second device interlayer dielectric layer 324 may bury or at least partially surround the second integrated elements 312. For example, the second integrated elements 312 may not be exposed by the second device interlayer dielectric layer 324. The second device interlayer dielectric layer 324 may include, for example, at least one selected from silicon oxide (SiO), silicon nitride (SiN), and silicon oxynitride (SiON). In some embodiments, the second device interlayer dielectric layer 324 may have a low-k dielectric material. The second device interlayer dielectric layer 324 may have a mono-layered structure or a multi-layered structure. When the second device interlayer dielectric layer 324 is provided as the multi-layered structure, an etch stop layer may be interposed between the dielectric layers. For example, the etch stop layer may be provided on a bottom surface of each dielectric layer. The etch stop layer may include, for example, one of silicon nitride (SiN), silicon oxynitride (SiON), and silicon carbonitride (SiCN).

The second device interlayer dielectric layer 324 may be provided therein with a second device wiring part 322 connected to the transistors TR. The second device wiring part 322 may include wiring patterns buried in the second device interlayer dielectric layer 324. For example, the wiring patterns may include redistribution patterns for horizontal wiring and via patterns for vertical connection. The second device wiring part 322 may vertically penetrate or extend into the second device interlayer dielectric layer 324 to connect to one of a source electrode, a drain electrode, and a gate electrode of the transistor TR. In some embodiments, the second device wiring part 322 may be connected to various components of the second integrated elements 312. The second device wiring part 322 may be positioned between top and bottom surfaces of the second device interlayer dielectric layer 324. A portion of the second device wiring part 322 may be exposed on the top surface of the second device interlayer dielectric layer 324. The second device wiring part 322 may include, for example, copper (Cu) or tungsten (W).

The second semiconductor chip 300 may further include one or more first chip pads 330 provided on the second wiring layer 320. The first chip pads 330 may be disposed adjacent to a first lateral surface 300a of the second semiconductor chip 300, which first lateral surface 300a is directed in a direction opposite to the first direction D1. The first chip pads 330 may be arranged along the first lateral surface 300a. The first chip pads 330 may be electrically connected to the second device wiring part 322. For example, a portion of the second device wiring part 322 may penetrate or extend into the second device interlayer dielectric layer 324 to be coupled to bottom surfaces of the first chip pads 330.

The second semiconductor chips 300 may be disposed in an offset stack structure (e.g., the second semiconductor chips 300 are not vertically aligned). For example, the second semiconductor chips 300 may be stacked obliquely in the first direction D1, and this configuration may form an upward cascade shape. For example, each of the second semiconductor chips 300 may protrude or extend in the first direction D1 from an underlying second semiconductor chip 300.

As the second semiconductor chips 300 are stepwise stacked, top surfaces of the second semiconductor chips 300 may be partially exposed. In one second semiconductor chip 300, a connection region may be defined to indicate the exposed portion of the top surface of the second semiconductor chip 300. In accordance with an offset stacking direction of the second semiconductor chips 300, the connection regions may be positioned adjacent to the first lateral surfaces 300a of the second semiconductor chips 300. In this disclosure, the expression “offset stacking direction” may be defined to refer to a shift direction relative to an underlying semiconductor chip when semiconductor chips are stacked. For example, in FIG. 1, the first direction D1 may be the offset stacking direction of the second semiconductor chips 300. For convenience of description below, a downside second semiconductor chip 300 may be defined to indicate an underlying second semiconductor chip 300 of arbitrary neighboring second semiconductor chips 300, and an upside second semiconductor chip 300 may be defined to indicate an immediately overlying second semiconductor chip 300 of arbitrary neighboring second semiconductor chips 300. The connection region of the downside second semiconductor chip 300 may be positioned in a direction opposite to the first direction D1 from the upside second semiconductor chip 300. The top surface of the second semiconductor chip 300 may be an active surface. For example, as discussed above, the first chip pads 330 may be provided on the connection region of the top surface of the second semiconductor chip 300. The first chip pads 330 may be connected to an integrated circuit of the second semiconductor chip 300.

A lowermost one of the second semiconductor chips 300 may be vertically aligned with the first semiconductor chip 200. The second semiconductor chips 300 may have their planar shapes the same as that of the first semiconductor chip 200. For example, a planar area and a width of each of the second semiconductor chips 300 may be the same as those of the first semiconductor chip 200. Therefore, the lowermost second semiconductor chip 300 may vertically overlap the first semiconductor chip 200. The first lateral surfaces 300a of the lowermost second semiconductor chip 300 may be vertically aligned with lateral surfaces of the first semiconductor chip 200. For example, the first semiconductor chip 200 may be interposed between the package substrate 100 and a stack of the second semiconductor chips 300.

Second adhesive layers 340 may be correspondingly provided on bottom surfaces of the second semiconductor chips 300. Each of the second semiconductor chips 300 may be attached thorough the second adhesive layer 340 to an underlying second semiconductor chip 300. For example, an upside second semiconductor chip 300 may be attached to the top surface of a downside second semiconductor chip 300 through the second adhesive layer 340 provided on the bottom surface of the upside second semiconductor chip 300. In this case, the upside second semiconductor chip 300 may expose the first chip pads 330 and the connection region of the downside second semiconductor chip 300. The lowermost second semiconductor chip 300 may be attached through the second adhesive layer 340 to a top surface of the first semiconductor chip 200. The second adhesive layer 340 may have a fourth thickness T4 of about 5 micrometers to about 20 micrometers. The second adhesive layers 340 may include a die attach film (DAF).

The second semiconductor chips 300 may be wire-bonded to the package substrate 100. The second semiconductor chips 300 may be connected through first connection wires BW1 to the package substrate 100. The first connection wires BW1 may connect the first chip pads 330 of the second semiconductor chips 300 to first signal pads 110 of the package substrate 100. For example, the first connection wires BW1 may each include first ends coupled to the first chip pads 330, second ends coupled to the first signal pads 110, and wire loops that connect the first ends to the second ends. When viewed in a plan view, the first signal pads 110 may be positioned in a direction opposite to the first direction D1 from the first chip stack CS1. In some embodiments, the first connection wires BW1 may connect neighboring second semiconductor chips 300 to each other. For example, the first connection wires BW1 may connect the first chip pads 330 of a downside second semiconductor chip 300 to the first chip pads 330 of an upside second semiconductor chip 300.

The first semiconductor chip 200 may be electrically insulated from the second semiconductor chips 300. For example, an active surface of the first semiconductor chip 200 may be covered or overlapped with the second adhesive layer 340 through which the lowermost second semiconductor chip 300 is attached to the first semiconductor chip 200. Thus, the first semiconductor chip 200 may be electrically floated in the first chip stack CS1 or in a semiconductor package.

According to some embodiments of the present disclosure, in the first chip stack CS1, the second semiconductor chips 300 may be provided as a stepwise structure having a cascade shape. As the lowermost second semiconductor chip 300 and the first semiconductor chip 200 vertically and completely overlap each other, the lowermost second semiconductor chip 300 and the first semiconductor chip 200 may constitute a support structure for supporting the stepwise structure. Accordingly, in semiconductor package fabrication process, the second semiconductor chips 300 may be rigidly stacked on the support structure formed of the lowermost second semiconductor chip 300 and the first semiconductor chip 200. This will be discussed in detail in a method of fabricating a semiconductor package. In addition, as a large thickness is given to the support structure formed of the lowermost second semiconductor chip 300 and the first semiconductor chip 200, even though a large number of semiconductor chips 300, 400, and 500 are provided on the first chip stack CS1 and a second chip stack CS2 which will be discussed below, the semiconductor chips 300, 400, and 500 may be firmly supported on the support structure. As a result, a semiconductor package may have increased structural stability.

Referring still to FIG. 1, a second chip stack CS2 may be provided on the first chip stack CS1. The second chip stack CS2 may have a configuration substantially the same as or similar to that of the first chip stack CS1.

The second chip stack CS2 may include a third semiconductor chip 400 and fourth semiconductor chips 500 that are stacked in the third direction D3 on the first chip stack CS1. The third semiconductor chip 400 and the fourth semiconductor chips 500 may be a memory chip. For example, the third semiconductor chip 400 and the fourth semiconductor chips 500 may include a dynamic random access memory (DRAM) or a NAND Flash memory. For convenience of description in this disclosure, the third semiconductor chip 400 and the fourth semiconductor chips 500 are distinguished from each other, but the third semiconductor chip 400 and the fourth semiconductor chips 500 may be the same semiconductor chip.

The third semiconductor chip 400 may be disposed on the first chip stack CS1. The third semiconductor chip 400 may include an integrated element therein. For example, the third semiconductor chip 400 may be a wafer-level die formed of a semiconductor, such as silicon (Si). The third semiconductor chip 400 may have a front surface and a rear surface. The rear surface of the third semiconductor chip 400 may be directed toward the first chip stack CS1. For example, the third semiconductor chips 400 may be face-up disposed on the first chip stack CS1. The third semiconductor chip 400 may have a thickness of about 30 micrometers to about 100 micrometers.

A configuration of the third semiconductor chip 400 may be the same as or similar to that of the first semiconductor chip 200 and that of the second semiconductor chips 300. For example, the third semiconductor chip 400 may include a third semiconductor substrate, third integrated elements formed on a top surface of the third semiconductor substrate, and a third wiring layer that covers or overlaps the top surface of the third semiconductor substrate and electrically connects to the third integrated elements.

A third adhesive layer 440 may be provided on a bottom surface of the third semiconductor chip 400. The third semiconductor chip 400 may be attached through the third adhesive layer 440 to the first chip stack CS1, for example, to an uppermost one of the second semiconductor chips 300. The third adhesive layer 440 may have a thickness of about 5 micrometers to about 20 micrometers. The third adhesive layer 440 may include a die attach film (DAF).

The third semiconductor chip 400 may be electrically insulated from the package substrate 100, the first semiconductor chip 200, and the second semiconductor chips 300. For example, the first semiconductor chip 200 may not include any of connection terminals, connection lines, and connection structures that are separately provided for electrical connection between the third semiconductor chip 400 and the package substrate 100, between the third semiconductor chip 400 and the first semiconductor chip 200, between the third semiconductor chip 400 and the second semiconductor chips 300.

The fourth semiconductor chips 500 may be disposed on the third semiconductor chip 400. The fourth semiconductor chips 500 may include an integrated element therein. For example, the fourth semiconductor chips 500 may be a wafer-level die formed of a semiconductor, such as silicon (Si). The fourth semiconductor chips 500 may have a front surface and a rear surface. The rear surfaces of the fourth semiconductor chips 500 may be directed toward the third semiconductor chip 400. For example, the fourth semiconductor chips 500 may be face-up disposed on the third semiconductor chip 400. The fourth semiconductor chips 500 may each have a thickness of about 30 micrometers to about 100 micrometers. As discussed above, each of the fourth semiconductor chips 500 may be of the same type as the third semiconductor chip 400. For example, a configuration of each of the fourth semiconductor chips 500 may be substantially the same as that of the third semiconductor chip 400. A planar shape of each of the fourth semiconductor chips 500 may be the same as that of the third semiconductor chip 400. Each of the fourth semiconductor chips 500 may have a width the same as that of the third semiconductor chip 400. Each of the fourth semiconductor chips 500 may have a planar area the same as that of the third semiconductor chip 400. The thickness of each of the fourth semiconductor chips 500 may be the same as that of the third semiconductor chip 400. The following will describe in detail a configuration of one fourth semiconductor chip 500.

The fourth semiconductor chip 500 may have the same configuration as that of the third semiconductor chip 400. For example, the fourth semiconductor chip 500 may include a fourth semiconductor substrate, fourth integrated elements formed on a top surface of the fourth semiconductor substrate, a fourth wiring layer that covers or overlaps the top surface of the fourth semiconductor substrate and electrically connects to the fourth integrated elements, and second chip pads 530 provided on the fourth wiring layer. The second chip pads 530 may be disposed adjacent to a lateral surface of the fourth semiconductor chip 500, where the lateral surface is directed in the first direction D1. The second chip pads 530 may be arranged along the lateral surface in the first direction D1 of the fourth semiconductor chip 500.

The fourth semiconductor chips 500 may be disposed in an offset stack structure. For example, the fourth semiconductor chips 500 may be stacked obliquely in a direction opposite to the first direction D1, and this configuration may form an upward cascade shape. For example, each of the fourth semiconductor chips 500 may protrude or extend in a direction opposite to the first direction D1 from an underlying fourth semiconductor chip 500.

As the fourth semiconductor chips 500 are stepwise stacked, top surfaces of the fourth semiconductor chips 500 may be partially exposed. In one fourth semiconductor chip 500, a connection region may be defined to indicate the exposed portion of the top surface of the fourth semiconductor chip 500. In accordance with an offset stacking direction of the fourth semiconductor chips 500, the connection regions may be positioned adjacent to the lateral surfaces in the first direction D1 of the fourth semiconductor chips 500. For example, in FIG. 1, a direction opposite to the first direction D1 may be the offset stacking direction of the fourth semiconductor chips 500. For convenience of description below, a downside fourth semiconductor chip 500 may be defined to indicate an underlying fourth semiconductor chip 500 of arbitrary neighboring fourth semiconductor chips 500, and an upside fourth semiconductor chip 500 may be defined to indicate an immediately overlying fourth semiconductor chip 500 of arbitrary neighboring fourth semiconductor chips 500. The connection region of the downside fourth semiconductor chip 500 may be positioned in the first direction D1 from the upside fourth semiconductor chip 500. The top surface of the fourth semiconductor chip 500 may be an active surface. For example, as discussed above, the second chip pads 530 may be provided on the connection region of the top surface of the fourth semiconductor chip 500. The second chip pads 530 may be connected to an integrated circuit of the fourth semiconductor chip 500.

A lowermost one of the fourth semiconductor chips 500 may be vertically aligned with the third semiconductor chip 400. The fourth semiconductor chips 500 may have their planar shapes the same as that of the third semiconductor chip 400. For example, a planar area and a width of each of the fourth semiconductor chips 500 may be the same as those of the third semiconductor chip 400. Therefore, the lowermost fourth semiconductor chip 500 may vertically overlap the third semiconductor chip 400. The lateral surfaces of the lowermost fourth semiconductor chip 500 may be vertically aligned with those of the third semiconductor chip 400. For example, the third semiconductor chip 400 may be interposed between the first chip stack CS1 and a stack of the fourth semiconductor chips 500.

Fourth adhesive layers 540 may be correspondingly provided on bottom surfaces of the fourth semiconductor chips 500. Each of the fourth semiconductor chips 500 may be attached through the fourth adhesive layer 540 to an underlying fourth semiconductor chip 500. For example, an upside fourth semiconductor chip 500 may be attached to the top surface of a downside fourth semiconductor chip 500 through the fourth adhesive layer 540 provided on the bottom surface of the upside fourth semiconductor chip 500. In this case, the upside fourth semiconductor chip 500 may expose the second chip pads 530 and the connection region of the downside fourth semiconductor chip 500. The lowermost fourth semiconductor chip 500 may be attached through the fourth adhesive layer 540 to a top surface of the third semiconductor chip 400. The fourth adhesive layer 540 may have a thickness of about 5 micrometers to about 20 micrometers. The fourth adhesive layer 540 may include a die attach film (DAF).

The fourth semiconductor chips 500 may be wire-bonded to the package substrate 100. The fourth semiconductor chips 500 may be connected through second connection wires BW2 to the package substrate 100. The second connection wires BW2 may connect the second chip pads 530 of the fourth semiconductor chips 500 to second signal pads 120 of the package substrate 100. For example, the second connection wires BW2 may include first ends coupled to the second chip pads 530, second ends coupled to the second signal pads 120, and wire loops that connect the first ends to the second ends. When viewed in a plan view, the second signal pads 120 may be positioned in the first direction D1 from the second chip stack CS2. In some embodiments, the second connection wires BW2 may connect neighboring fourth semiconductor chips 500 to each other. For example, the second connection wires BW2 may connect the second chip pads 530 of a downside fourth semiconductor chip 500 to the second chip pads 530 of an upside fourth semiconductor chip 500.

The third semiconductor chip 400 may be electrically insulated from the fourth semiconductor chips 500. For example, an active surface of the third semiconductor chip 400 may be covered with or overlapped by the fourth adhesive layer 540 through which the lowermost fourth semiconductor chip 500 is attached to the third semiconductor chip 400. Thus, the third semiconductor chip 400 may be electrically floated in the second chip stack CS2 or in a semiconductor package.

According to some embodiments of the present disclosure, in the second chip stack CS2, the fourth semiconductor chips 500 may be provided as a stepwise structure having a cascade shape. As the lowermost fourth semiconductor chip 500 and the third semiconductor chip 400 vertically and completely overlap each other, the lowermost fourth semiconductor chip 500 and the third semiconductor chip 400 may constitute a support structure for supporting the stepwise structure. Accordingly, in semiconductor package fabrication process, the fourth semiconductor chips 500 may be rigidly stacked on the support structure formed of the lowermost fourth semiconductor chip 500 and the third semiconductor chip 400. This will be discussed in detail in a method of fabricating a semiconductor package. In addition, as a large thickness is given to the support structure formed of the lowermost fourth semiconductor chip 500 and the third semiconductor chip 400, even though a large number of semiconductor chips 400 and 500 are provided on the second chip stack CS2, the semiconductor chips 400 and 500 may be firmly supported on the support structure. As a result, a semiconductor package may have increased structural stability.

Referring to FIG. 1, a molding layer 600 may be provided on the package substrate 100. The molding layer 600 may cover or overlap the first chip stack CS1 and the second chip stack CS2. The layer 600 may include a dielectric polymer material, such as epoxy molding compound molding (EMC).

In the embodiments that follow, a detailed description of technical features repetitive to those discussed above with reference to FIGS. 1 and 2 will be omitted, and a difference thereof will be discussed in detail. The same reference numerals may be allocated to the same components as those of the semiconductor package discussed above according to some embodiments of the present disclosure.

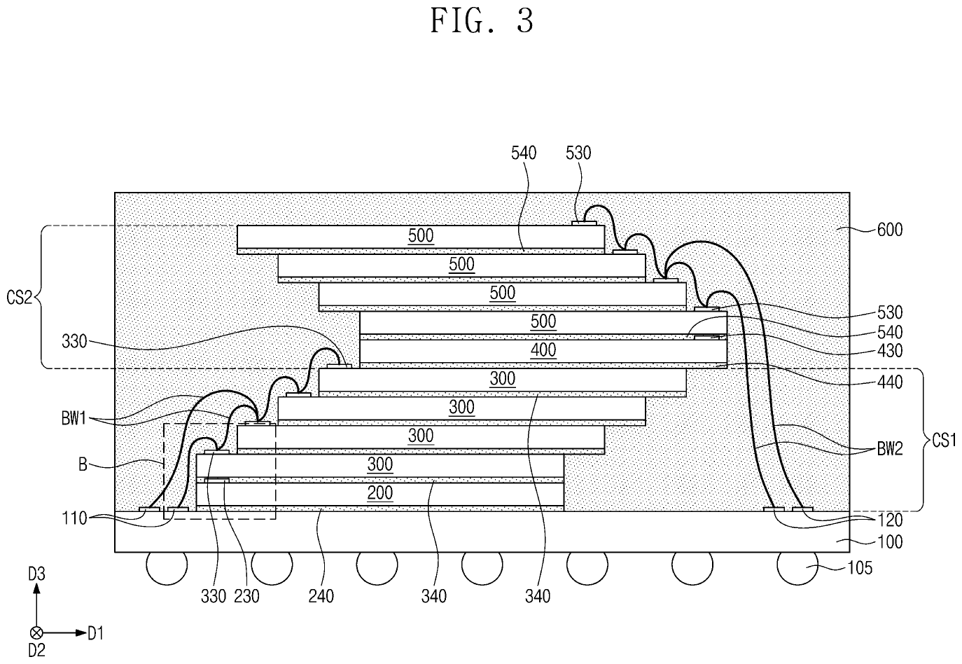

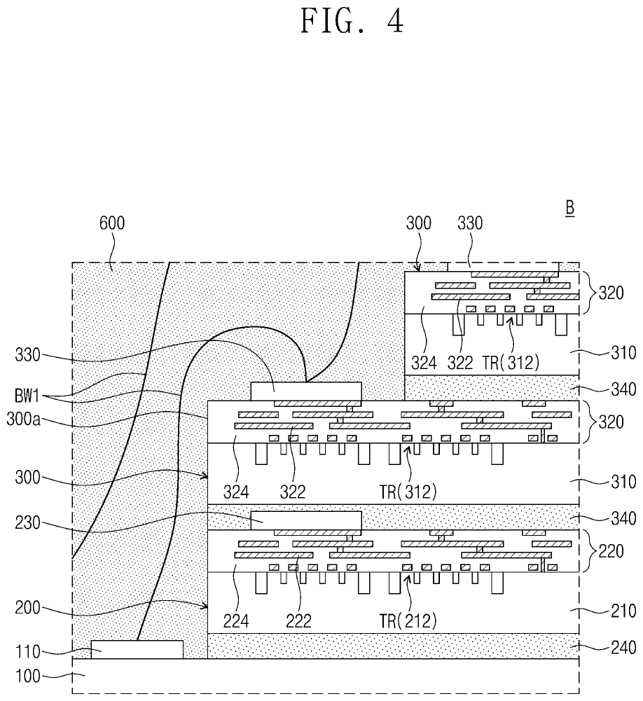

FIG. 3 illustrates a cross-sectional view showing a semiconductor package according to some embodiments of the present disclosure. FIG. 4 illustrates an enlarged view showing section B of FIG. 3.

Referring to FIGS. 3 and 4, the first semiconductor chip 200 may have the same configuration as that of the second semiconductor chips 300.

The first semiconductor chip 200 may further include one or more third chip pads 230 provided on the first wiring layer 220. The third chip pads 230 may be disposed adjacent to a lateral surface of the first semiconductor chip 200, which lateral surface is directed in a direction opposite to the first direction D1. The third chip pads 230 may be arranged along the lateral surface in the direction opposite to the first direction D1 of the first semiconductor chip 200. The third chip pads 230 may be electrically connected to the first device wiring part 222. For example, a portion of the first device wiring part 222 may penetrate or extend into the first device interlayer dielectric layer 224 to be coupled to bottom surfaces of the third chip pads 230.

The lowermost second semiconductor chip 300 may be attached through the second adhesive layer 340 to the first semiconductor chip 200. The second adhesive layer 340 may cover or overlap an entirety of the top surface of the first semiconductor chip 200. In this case, the third chip pads 230 of the first semiconductor chip 200 may be covered with or overlapped by the second adhesive layer 340.

The third semiconductor chip 400 may have the same configuration as that of the fourth semiconductor chips 500.

The third semiconductor chip 400 may further include one or more fourth chip pads 430 provided on the third wiring layer. The fourth chip pads 430 may be disposed adjacent to the lateral surface of the third semiconductor chip 400, and the lateral surface is directed in the first direction D1. The fourth chip pads 430 may be arranged along the lateral surface in the first direction D1 of the third semiconductor chip 400. The fourth chip pads 430 may be electrically connected to a third device wiring part provided in the third semiconductor chip 400. For example, a portion of the third device wiring part may penetrate or extend into a third device interlayer dielectric layer to be coupled to bottom surfaces of the fourth chip pads 430.

The lowermost fourth semiconductor chip 500 may be attached through the fourth adhesive layer 540 to the third semiconductor chip 400. The fourth adhesive layer 540 may cover or overlap an entirety of the top surface of the third semiconductor chip 400. In this case, the fourth chip pads 430 of the third semiconductor chip 400 may be covered with or overlapped by the fourth adhesive layer 540.

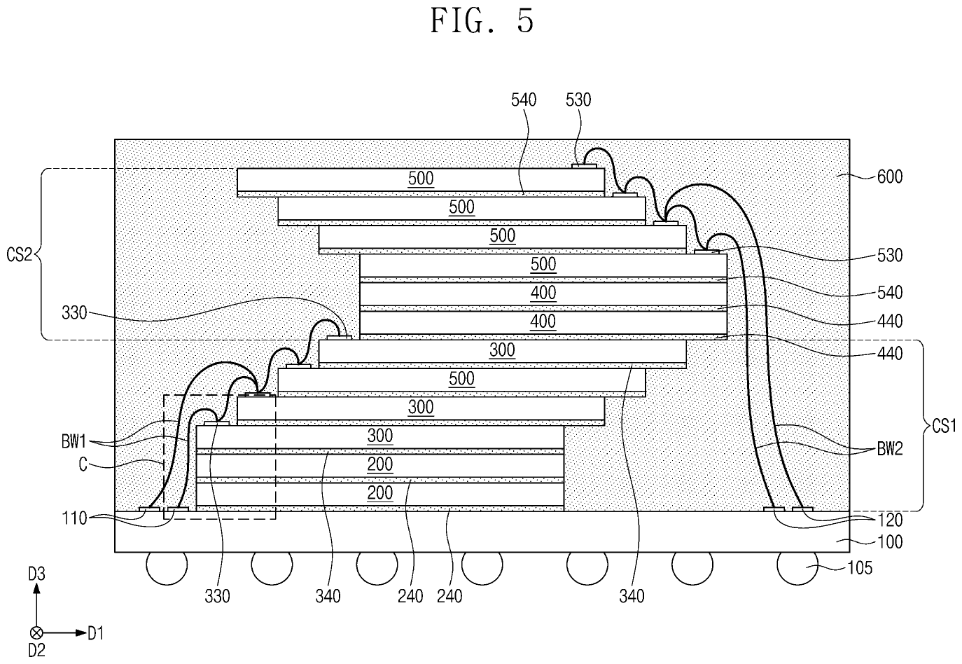

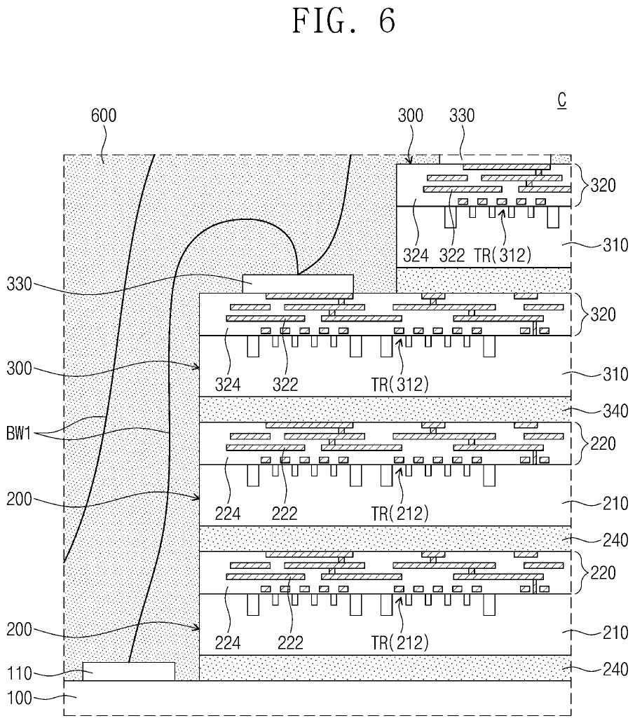

FIG. 5 illustrates a cross-sectional view showing a semiconductor package according to some embodiments of the present disclosure. FIG. 6 illustrates an enlarged view showing section C of FIG. 5.

Referring to FIGS. 5 and 6, the first semiconductor chip 200 may be provided in plural. The first semiconductor chips 200 may be stacked on the package substrate 100.

The first semiconductor chips 200 may be vertically aligned with each other. For example, the first semiconductor chips 200 may vertically overlap each other. The first semiconductor chips 200 may have their lateral surfaces that are vertically aligned with each other.

The second semiconductor chips 300 may be disposed in an offset stack structure on an upside first semiconductor chip 200.

A lowermost one of the second semiconductor chips 300 may be vertically aligned with the first semiconductor chips 200. The second semiconductor chips 300 may have a planar shape the same as that of the first semiconductor chips 200. For example, a planar area and a width of each of the second semiconductor chips 300 may be the same as those of each of the first semiconductor chips 200. Therefore, the lowermost second semiconductor chip 300 may vertically overlap the first semiconductor chips 200. The lowermost second semiconductor chip 300 may have lateral surfaces vertically aligned with those of an upside first semiconductor chip 200 and those of a downside first semiconductor chip 200.

According to some embodiments of the present disclosure, a plurality of stacked first semiconductor chips 200 may be provided below the second semiconductor chips 300. The lowermost second semiconductor chip 300 and the first semiconductor chips 200 may constitute a support structure that supports the stepwise structure of the second semiconductor chips 300. For example, as the first semiconductor chip 200 is provided in plural, the support structure may have an increased thickness. Therefore, even though a large number of the semiconductor chips 300, 400, and 500 are provided on the first chip stack CS1 and the second chip stack CS2, the semiconductor chips 300, 400, and 500 may be firmly supported on the support structure. As a result, a semiconductor package may have increased structural stability.

The third semiconductor chip 400 may be provided in plural. The third semiconductor chips 400 may be stacked on the first chip stack CS1.

The third semiconductor chips 400 may be vertically aligned with each other. For example, the third semiconductor chips 400 may vertically overlap each other. The third semiconductor chips 400 may have their lateral surfaces that are vertically aligned with each other.

The fourth semiconductor chips 500 may be disposed in an offset stack structure on an upside third semiconductor chip 400.

A lowermost one of the fourth semiconductor chips 500 may be vertically aligned with the third semiconductor chips 400. The fourth semiconductor chips 500 may have a planar shape the same as that of the third semiconductor chips 400. For example, a planar area and a width of each of the fourth semiconductor chips 500 may be the same as those of each of the third semiconductor chips 400. Therefore, the lowermost fourth semiconductor chip 500 may vertically overlap the third semiconductor chips 400. The lowermost fourth semiconductor chip 500 may have lateral surfaces vertically aligned with those of an upside third semiconductor chip 400 and those of a downside third semiconductor chip 400.

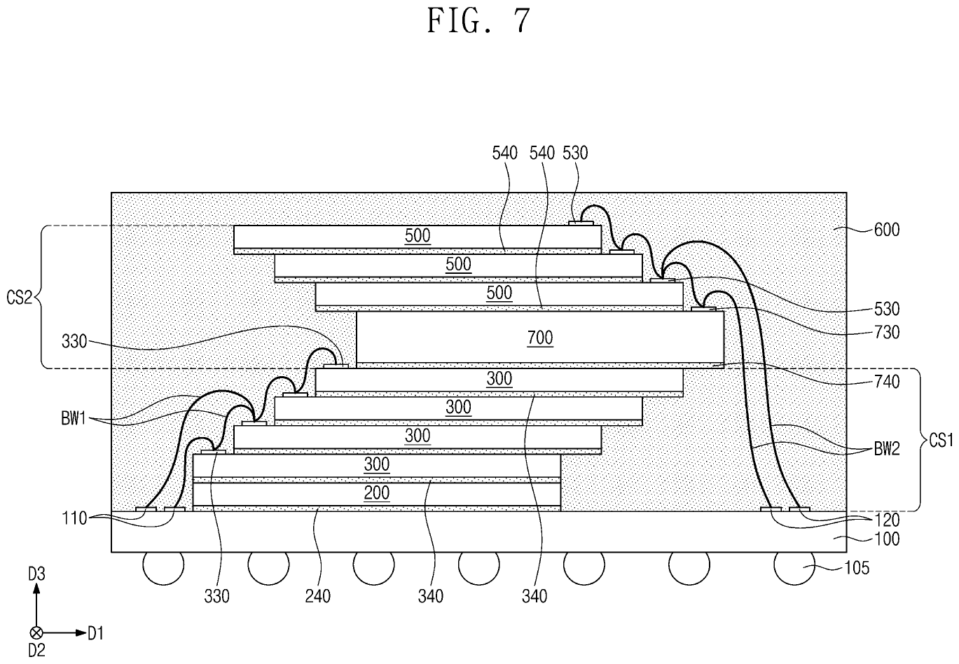

FIG. 7 illustrates a cross-sectional view showing a semiconductor package according to some embodiments of the present disclosure.

Referring to FIG. 7, the second chip stack CS2 may include a fifth semiconductor chip 700 instead of the third semiconductor chip (see 400 of FIG. 1) and the lowermost fourth semiconductor chip (see 500 of FIG. 1).

The fifth semiconductor chip 700 may be disposed on the first chip stack CS1. The fifth semiconductor chip 700 may include an integrated element therein. For example, the fifth semiconductor chip 700 may be a wafer-level die formed of a semiconductor, such as silicon (Si). The fifth semiconductor chip 700 may have a front surface and a rear surface. The rear surface of the fifth semiconductor chip 700 may be directed toward the first chip stack CS1. For example, the fifth semiconductor chips 700 may be face-up disposed on the first chip stack CS1. The fifth semiconductor chip 700 may have a thickness greater than those of the fourth semiconductor chips 500. The fifth semiconductor chip 700 may have a thickness of about 60 micrometers to about 300 micrometers.

The fifth semiconductor chip 700 may have the same configuration as that of the fourth semiconductor chips 500. For example, the fifth semiconductor chip 700 may include a fifth semiconductor substrate, fifth integrated elements formed on a top surface of the fifth semiconductor substrate, a fifth wiring layer that covers or overlaps the top surface of the fifth semiconductor substrate and electrically connects to the fifth integrated elements, and fifth chip pads 730 provided on the fifth wiring layer. The fifth integrated elements may be of the same type as the fourth integrated element of the fourth semiconductor chips 500. For example, the fifth semiconductor chip 700 may have a different thickness from those of the fourth semiconductor chips 500, but the fifth semiconductor chip 700 and the fourth semiconductor chips 500 may be the same chip in terms of function. The fifth chip pads 730 may be disposed adjacent to a lateral surface of the fifth semiconductor chip 700, which lateral surface is directed in the first direction D1. The fifth chip pads 730 may be arranged along the lateral surface in the first direction D1 of the fifth semiconductor chip 700.

A fifth adhesive layer 740 may be provided on a bottom surface of the fifth semiconductor chip 700. The fifth semiconductor chip 700 may be attached through the fifth adhesive layer 740 to the first chip stack CS1, for example, to an uppermost one of the second semiconductor chips 300. The fifth adhesive layer 740 may have a thickness of about 5 micrometers to about 20 micrometers. The fifth adhesive layer 740 may include a die attach film (DAF).

The fourth semiconductor chips 500 may be stacked on the fifth semiconductor chip 700.

The fifth semiconductor chip 700 and the fourth semiconductor chips 500 may be disposed in an offset stack structure. For example, the fifth semiconductor chip 700 and the fourth semiconductor chips 500 may be stacked obliquely in a direction opposite to the first direction D1, and this configuration may form an upward cascade shape. For example, the fifth semiconductor chip 700 and the fourth semiconductor chips 500 may each protrude or extend in a direction opposite to the first direction D1 from an underlying semiconductor chip.

The fifth semiconductor chip 700 and the fourth semiconductor chips 500 may be wire-bonded to the package substrate 100. The fifth semiconductor chip 700 and the fourth semiconductor chips 500 may be connected through the second connection wires BW2 to the package substrate 100. For example, the second connection wires BW2 may connect the second signal pads 120 of the package substrate 100 to the fifth chip pads 730 of the fifth semiconductor chip 700 or the second chip pads 530 of the fourth semiconductor chips 500. The second connection wires BW2 may include first ends coupled to the fifth chip pads 730 or the second chip pads 530, second ends coupled to the second signal pads 120, and wire loops that connect the first ends to the second ends. When viewed in a plan view, the second signal pads 120 may be positioned in the first direction D1 from the second chip stack CS2. In some embodiments, the second connection wires BW2 may connect neighboring fourth semiconductor chip 500 to each other or may connect the fifth semiconductor chip 700 to the lowermost fourth semiconductor chip 500. For example, the second connection wires BW2 may connect the second chip pads 530 of a downside fourth semiconductor chip 500 to the second chip pads 530 of an upside fourth semiconductor chip 500. In some embodiments, the second connection wires BW2 may connect the second chip pads 530 of the lowermost fourth semiconductor chip 500 to the fifth chip pads 730 of the fifth semiconductor chip 700.

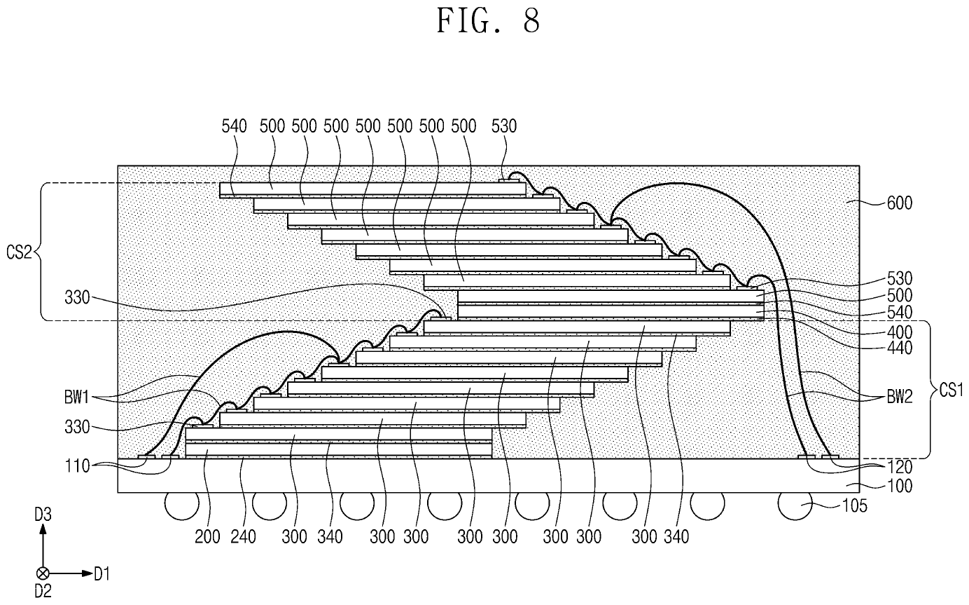

FIG. 8 illustrates a cross-sectional view showing a semiconductor package according to some embodiments of the present disclosure.

In the embodiments of FIGS. 1 to 7, it is illustrated and described that the first chip stack CS1 and the second chip stack CS2 include four second semiconductor chips 300 and four fourth semiconductor chips 500, respectively, but the present disclosure is not limited thereto.

Referring to FIG. 8, the first chip stack CS1 may include eight second semiconductor chips 300 that are stacked on the first semiconductor chip 200. The second chip stack CS2 may include eight fourth semiconductor chips 500 that are stacked on the third semiconductor chip 400. The present disclosure, however, is not limited thereto. According to some embodiments, the first chip stack CS1 may include two, six, or more than eight second semiconductor chips 300 that are stacked on the first semiconductor chip 200. The second chip stack CS2 may include two, six, or more than eight fourth semiconductor chips 500 that are stacked on the third semiconductor chip 400.

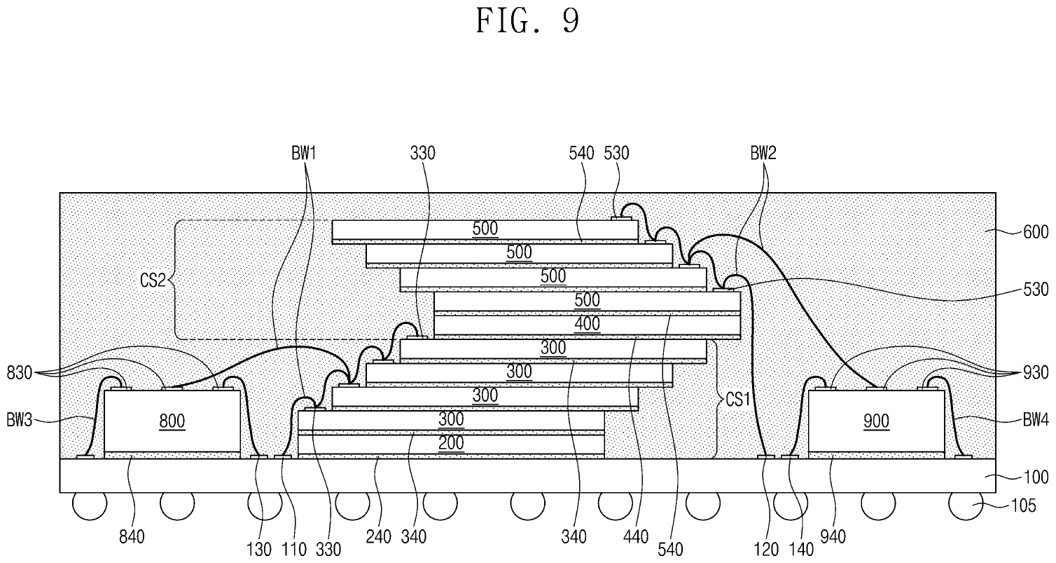

FIG. 9 illustrates a cross-sectional view showing a semiconductor package according to some embodiments of the present disclosure.

Referring to FIG. 9, a semiconductor package may further include a sixth semiconductor chip 800 and a seventh semiconductor chip 900.

The sixth semiconductor chip 800 may be disposed on the package substrate 100. The sixth semiconductor chip 800 may be disposed spaced apart in a direction opposite to the first direction D1 from the first chip stack CS1. The sixth semiconductor chip 800 may have a thickness greater than those of the first and second semiconductor chips 200 and 300. The thickness of the sixth semiconductor chip 800 may be less than a total thickness of the first chip stack CS1. The sixth semiconductor chip 800 may be a logic chip. For example, the sixth semiconductor chip 800 may include a controller.

A top surface of the sixth semiconductor chip 800 may be an active surface. For example, sixth chip pads 830 may be provided on the top surface of the sixth semiconductor chip 800. The sixth chip pads 830 may be connected to an integrated circuit of the sixth semiconductor chip 800.

The sixth semiconductor chip 800 may be wire-bonded to the package substrate 100. The sixth semiconductor chip 800 may be connected through third connection wires BW3 to the package substrate 100. For example, the third connection wires BW3 may connect the sixth chip pads 830 of the sixth semiconductor chip 800 to third signal pads 130 of the package substrate 100. The third signal pads 130 may be positioned either between the first chip stack CS1 and the sixth semiconductor chip 800 or in a direction opposite to the first direction D1 from the sixth semiconductor chip 800. In one variation, the third signal pads 130 may be positioned in the second direction D2 or in a direction opposite to the second direction D2 from the sixth semiconductor chip 800.

A sixth adhesive layer 840 may be provided on a bottom surface of the sixth semiconductor chip 800. The sixth semiconductor chip 800 may be attached through the sixth adhesive layer 840 to the package substrate 100. The sixth adhesive layer 840 may include a die attach film (DAF).

Ones of the first connection wires BW1 of the first chip stack CS1 may be coupled to the sixth chip pads 830 of the sixth semiconductor chip 800.

The seventh semiconductor chip 900 may be disposed on the package substrate 100. The seventh semiconductor chip 900 may be disposed spaced apart in the first direction D1 from the second chip stack CS2. The seventh semiconductor chip 900 may have a thickness greater than those of the first and second semiconductor chips 200 and 300. The thickness of the seventh semiconductor chip 900 may be less than a total thickness of the first chip stack CS1. The seventh semiconductor chip 900 may be a logic chip. For example, the seventh semiconductor chip 900 may include a controller. A top surface of the seventh semiconductor chip 900 may be an active surface. For example, seventh chip pads 930 may be provided on the top surface of the seventh semiconductor chip 900. The seventh chip pads 930 may be connected to an integrated circuit of the seventh semiconductor chip 900.

The seventh semiconductor chip 900 may be wire-bonded to the package substrate 100. The seventh semiconductor chip 900 may be connected through fourth connection wires BW4 to the package substrate 100. For example, the fourth connection wires BW4 may connect the seventh chip pads 930 of the seventh semiconductor chip 900 to fourth signal pads 140 of the package substrate 100. The fourth signal pads 140 may be positioned either between the second chip stack CS2 and the seventh semiconductor chip 900 or in the first direction D1 from the seventh semiconductor chip 900. In some embodiments, differently from that shown, the fourth signal pads 140 may be positioned in the second direction D2 or in a direction opposite to the second direction D2 from the seventh semiconductor chip 900.

A seventh adhesive layer 940 may be provided on a bottom surface of the seventh semiconductor chip 900. The seventh semiconductor chip 900 may be attached through the seventh adhesive layer 940 to the package substrate 100. The seventh adhesive layer 940 may include a die attach film (DAF).

Ones of the second connection wires BW2 of the second chip stack CS2 may be coupled to the seventh chip pads 930 of the seventh semiconductor chip 900.

According to some embodiments of the present disclosure, a semiconductor package may include only one of the sixth semiconductor chip 800 and the seventh semiconductor chip 900.

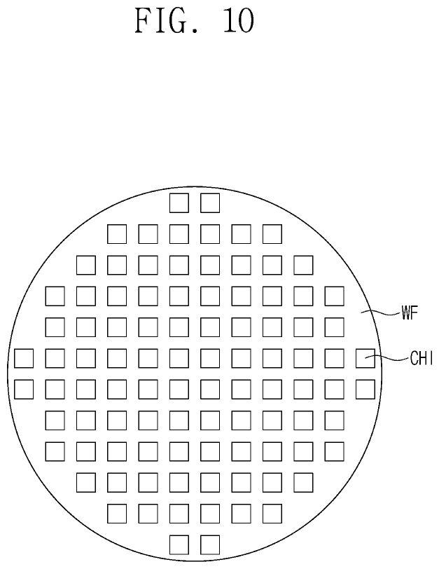

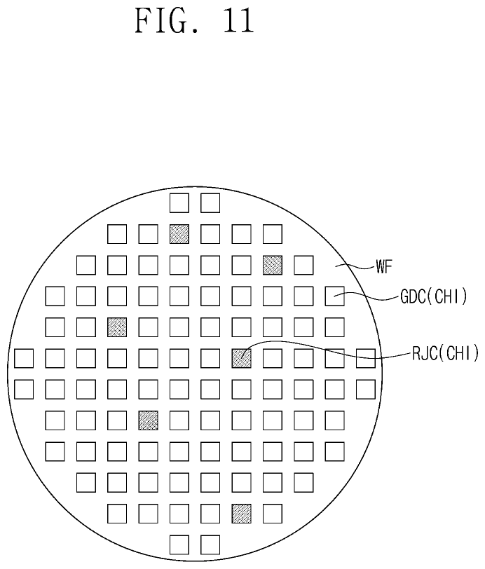

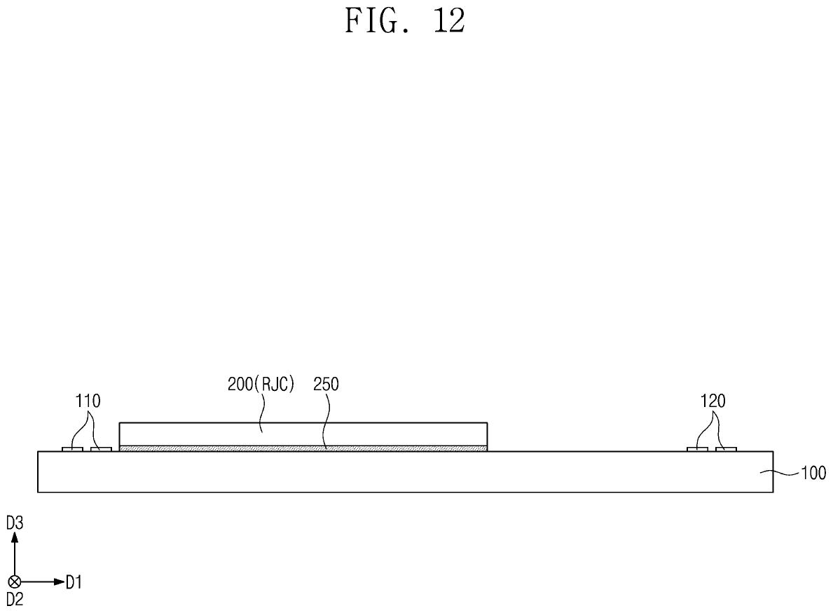

FIGS. 10 and 11 illustrate plan views showing a semiconductor wafer in a method of fabricating a semiconductor package according to some embodiments of the present disclosure. FIGS. 12 to 19 illustrate cross-sectional views showing a method of fabricating a semiconductor package according to some embodiments of the present disclosure.

Referring to FIG. 10, a semiconductor wafer WF may be provided. For example, the semiconductor wafer WF may be a silicon (Si) wafer.

The semiconductor wafer WF may undergo a typical process to form a plurality of semiconductor chips CHI. For example, integrated elements may be formed on one surface of the semiconductor wafer WF, and a wiring layer may be formed on the one surface of the semiconductor wafer WF to cover/overlap and electrically connect to the integrated elements.

Referring to FIG. 11, the semiconductor chips CHI may be tested. At least one of the semiconductor chips CHI formed on the semiconductor wafer WF may be a semiconductor chip RJC (referred to hereinafter as a defective chip) that is determined to be defective in a test process of the semiconductor chips CHI. At least another of the semiconductor chips CHI formed on the semiconductor wafer WF may be a semiconductor chip GDC (referred to hereinafter as a normal chip) that is determined to be normal in a test process of the semiconductor chips CHI. The normal chips GDC and the defective chips RJC may have the same circuit structure and wiring structure of integrated elements thereof. Different from the normal chips GDC, the defective chips RJC may not normally operate their functions.

Referring to FIG. 12, a package substrate 100 may be provided. The package substrate 100 may be a printed circuit board (PCB) with signal patterns on a top surface thereof. The package substrate 100 may include first signal pads 110 and second signal pads 120.

A first semiconductor chip 200 may be attached to the package substrate 100. For example, a first adhesive member 250 may be provided on an inactive surface of the first semiconductor chip 200. The first semiconductor chip 200 may be attached through the first adhesive member 250 to the top surface of the package substrate 100. The first semiconductor chip 200 may be attached between first signal pads 110 and second signal pads 120 of the package substrate 100. For example, when viewed in a plan view, the first signal pads 110 may be positioned in a direction opposite to the first direction D1 from the first semiconductor chip 200. The first semiconductor chip 200 may have a top surface as an active surface. The first semiconductor chip 200 may be a defective chip RJC of the semiconductor chips CHI on the semiconductor wafer WF tested in FIG. 11. The attachment of the first semiconductor chip 200 may include selecting a defective chip RJC from the semiconductor wafer WF, coating the first adhesive member 250 on an inactive surface of the selected defective chip RJC, and placing the selected defective chip RJC on the package substrate 100. According to some embodiments, third chip pads 230 of the first semiconductor chip 200 may be provided on the top surface of the first semiconductor chip 200. In this case, it may be possible to fabricate a semiconductor package discussed with reference to FIGS. 3 and 4. The following description will focus on the embodiment of FIG. 12.

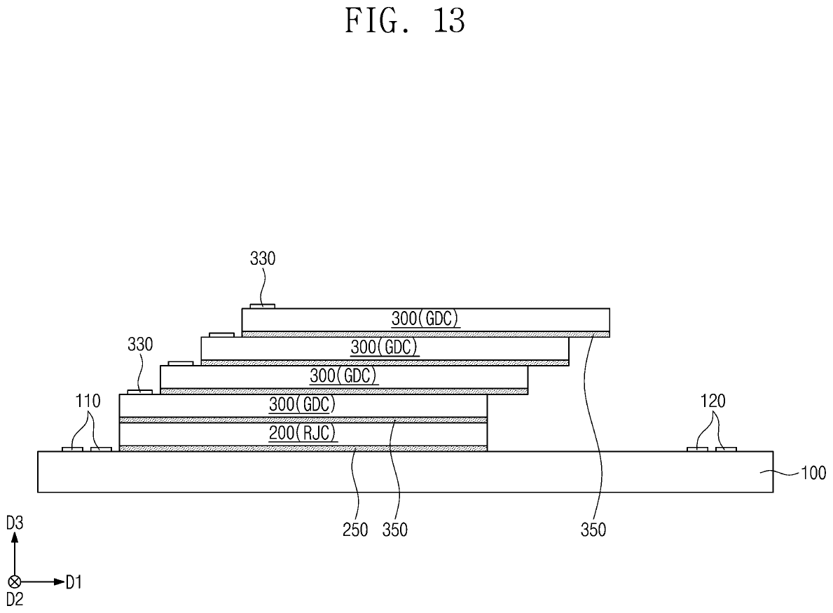

Referring to FIG. 13, a second semiconductor chip 300 may be provided on the first semiconductor chip 200. For example, a second adhesive member 350 may be provided on an inactive surface of the second semiconductor chip 300. The second adhesive member 350 of the second semiconductor chip 300 may be attached to the top surface of the first semiconductor chip 200. When the first semiconductor chip 200 has the third chip pads 230, the third chip pads 230 may be inserted into the second adhesive member 350. The second semiconductor chip 300 may have a top surface as an active surface. For example, first chip pads 330 of the second semiconductor chip 300 may be provided on the top surface of the second semiconductor chip 300. The second semiconductor chip 300 may be a normal chip GDC of the semiconductor chips CHI on the semiconductor wafer WF tested in FIG. 11. For example, the attachment of the second semiconductor chip 300 may include selecting a normal chip GDC from the semiconductor wafer WF, coating the second adhesive member 350 on an inactive surface of the selected normal chip GDC, and placing the selected normal chip GDC on the first semiconductor chip 200.

A plurality of second semiconductor chips 300 may be stacked on the second semiconductor chip 300 (referred to hereinafter as a lowermost second semiconductor chip) attached to the first semiconductor chip 200. For example, a second adhesive member 350 may be provided on an inactive surface of the second semiconductor chip 300. The second adhesive member 350 of the second semiconductor chip 300 may be in contact with the top surface of the lowermost second semiconductor chip 300. The process mentioned above may be used to stack a plurality of second semiconductor chips 300. The second semiconductor chips 300 may be stacked in an offset stack structure. The second semiconductor chip 300 may have their top surfaces as active surfaces. The first chip pads 330 of the second semiconductor chips 300 may thus be exposed.

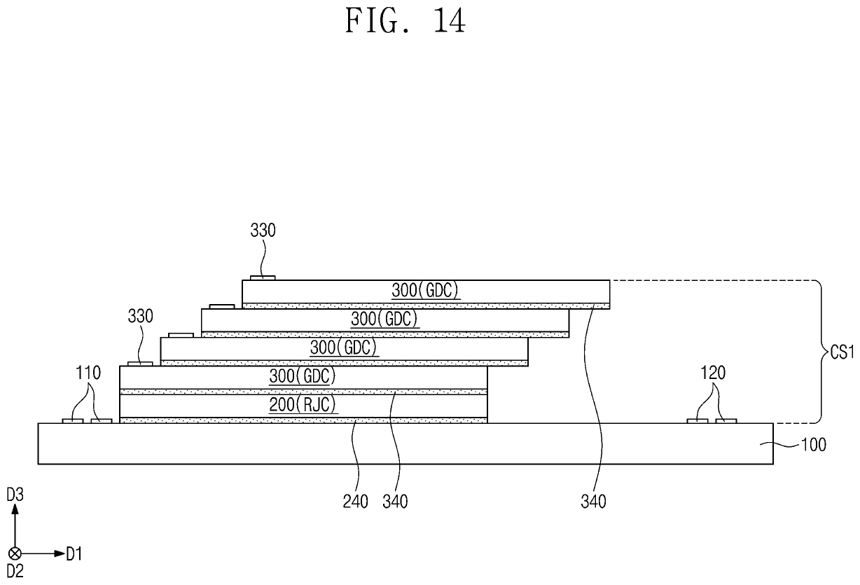

Referring to FIG. 14, the first adhesive member 250 and the second adhesive members 350 may be cured to form a first adhesive layer 240 and second adhesive layers 340. The curing of the first adhesive member 250 and the second adhesive members 350 may be performed at the same time in a single process. For example, the curing process may include an annealing process or a thermal compression process. The curing of the first adhesive member 250 and the second adhesive members 350 may cause the first semiconductor chip 200 to be rigidly attached to the package substrate 100 and the second semiconductor chips 300 to be rigidly attached to the first semiconductor chip 200 or another second semiconductor chip 300. Through the processes mentioned above, a first chip stack CS1 may be formed.

When the first semiconductor chip 200 and the second semiconductor chips 300 are formed to include different chips from each other, for example when the first semiconductor chip 200 is formed as a dummy chip of bulk silicon, the first semiconductor chip 200 and the second semiconductor chips 300 may be formed by using wafers different from each other. In this case, after the first semiconductor chip 200 is attached to the package substrate 100, a semiconductor wafer replacement process may be required for selection of the second semiconductor chips 300. Thus, the number of process steps may increase, and a process time may become longer.

According to some embodiments of the present disclosure, the first semiconductor chip 200 and the second semiconductor chips 300 may be formed of the same type. A single semiconductor wafer WF may thus be used to form not only the first semiconductor chip 200 that is provided below the second semiconductor chips 300 and supports the first chip stack CS1, but also the second semiconductor chips 300 stacked on the first semiconductor chip 200. For example, as the first semiconductor chip 200 and the second semiconductor chips 300 can be selected from one semiconductor wafer WF, the first and second semiconductor chips 300 may be successively stacked and attached. When the first and second semiconductor chips 200 and 300 are stacked and attached, there may be no need for replacement of the semiconductor wafer WF. Therefore, after the first semiconductor chip 200 is attached to the package substrate 100, the same semiconductor wafer WF may be used to successively attach the second semiconductor chips 300 to the first semiconductor chip 200. In addition, in a subsequent process, the first adhesive member 250 and the second adhesive member 350 may be cured simultaneously with each other. It may thus be possible to provide a method of fabricating a semiconductor package whose fabrication process is simplified and whose process time is reduced.

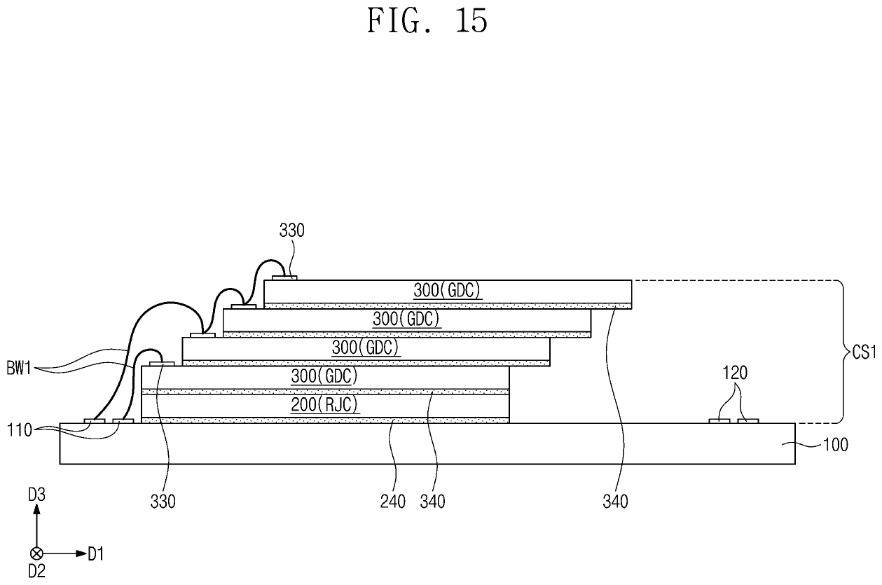

Referring to FIG. 15, the second semiconductor chips 300 may be wire-bonded to the package substrate 100. For example, a capillary may be provided on one of the first chip pads 330 of the second semiconductor chips 300. The capillary may melt a wire introduced therein to thereby form a ball at a bottom end of the capillary. The capillary may move onto the one first chip pad 330 to allow the ball to be attached to the one first chip pad 330. The capillary may move onto one of the first signal pads 110 or one of the first chip pads 330 of an adjacent another second semiconductor chip 300. In this step, a wire released from the capillary may form a wire loop. The capillary may form a ball attached to the one first signal pad 110 at one end of the wire loop. Therefore, first connection wires BW1 may be formed which connect the first chip pads 330 to each other or connect the first chip pads 330 to the first signal pads 110.

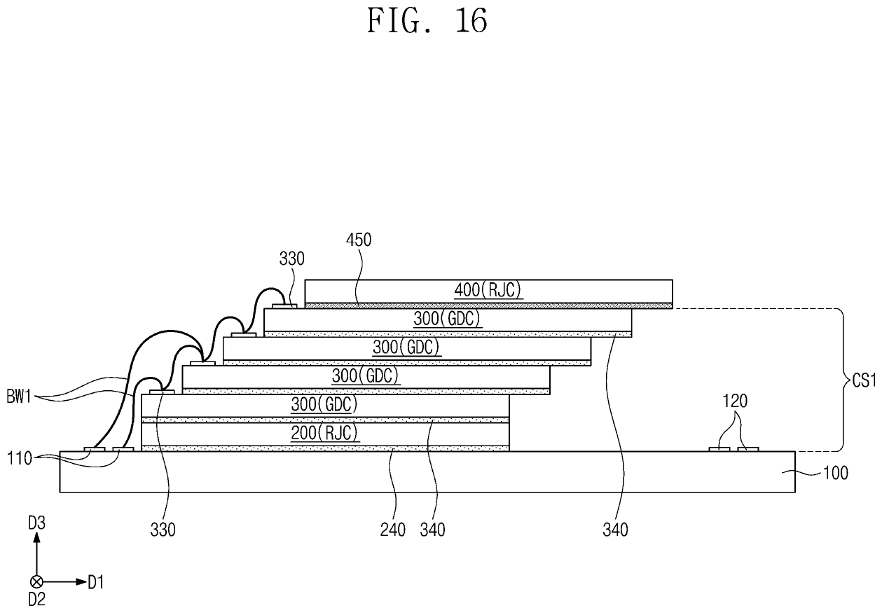

Referring to FIG. 16, a third semiconductor chip 400 may be attached to the first chip stack CS1. For example, a third adhesive member 450 may be provided on an inactive surface of the third semiconductor chip 400. The third semiconductor chip 400 may be attached through the third adhesive member 450 to a top surface of the first chip stack CS1 or a top surface of an uppermost second semiconductor chip 300. A top surface of the third semiconductor chip 400 may be an active surface. The third semiconductor chip 400 may be a defective chip RJC of the semiconductor chips CHI on the semiconductor wafer WF tested in FIG. 11. The attachment of the third semiconductor chip 400 may include selecting a defective chip RJC from the semiconductor wafer WF, coating the third adhesive member 450 on an inactive surface of the selected defective chip RJC, and placing the selected defective chip RJC on the first chip stack CS1. According to some embodiments, fourth chip pads 430 of the third semiconductor chip 400 may be provided on the top surface of the third semiconductor chip 400. In this case, it may be possible to fabricate a semiconductor package discussed with reference to FIGS. 3 and 4. The following description will focus on the embodiment of FIG. 16.

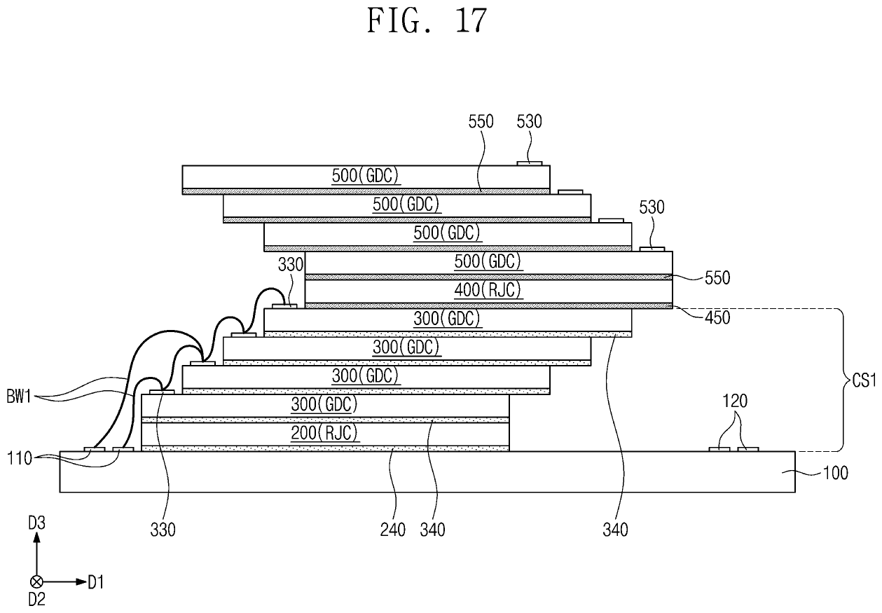

Referring to FIG. 17, a fourth semiconductor chip 500 may be provided on the third semiconductor chip 400. For example, a fourth adhesive member 550 may be provided on an inactive surface of the fourth semiconductor chip 500. The fourth adhesive member 550 of the fourth semiconductor chip 500 may be attached to the top surface of the third semiconductor chip 400. When the third semiconductor chip 400 has the fourth chip pads 430, the fourth chip pads 430 may be inserted into the fourth adhesive member 550. A top surface of the fourth semiconductor chip 500 may be an active surface. For example, second chip pads 530 of the fourth semiconductor chip 500 may be provided on the top surface of the fourth semiconductor chip 500. The fourth semiconductor chip 500 may be a normal chip GDC of the semiconductor chips CHI on the semiconductor wafer WF tested in FIG. 11. For example, the attachment of the fourth semiconductor chip 500 may include selecting a normal chip GDC from the semiconductor wafer WF, coating the fourth adhesive member 550 on an inactive surface of the selected normal chip GDC, and placing the selected normal chip GDC on the third semiconductor chip 400.

A plurality of fourth semiconductor chips 500 may be stacked on the fourth semiconductor chip 500 (referred to hereinafter as a lowermost fourth semiconductor chip) attached to the third semiconductor chip 400. For example, a fourth adhesive member 550 may be provided on the inactive surface of the fourth semiconductor chip 500. The fourth adhesive member 550 of the fourth semiconductor chip 500 may be in contact with the top surface of the lowermost fourth semiconductor chip 500. The process mentioned above may be used to stack a plurality of fourth semiconductor chips 500. The fourth semiconductor chips 500 may be stacked in an offset stack structure. The top surfaces of the fourth semiconductor chips 500 may be active surfaces. The second chip pads 530 of the fourth semiconductor chips 500 may be thus exposed.

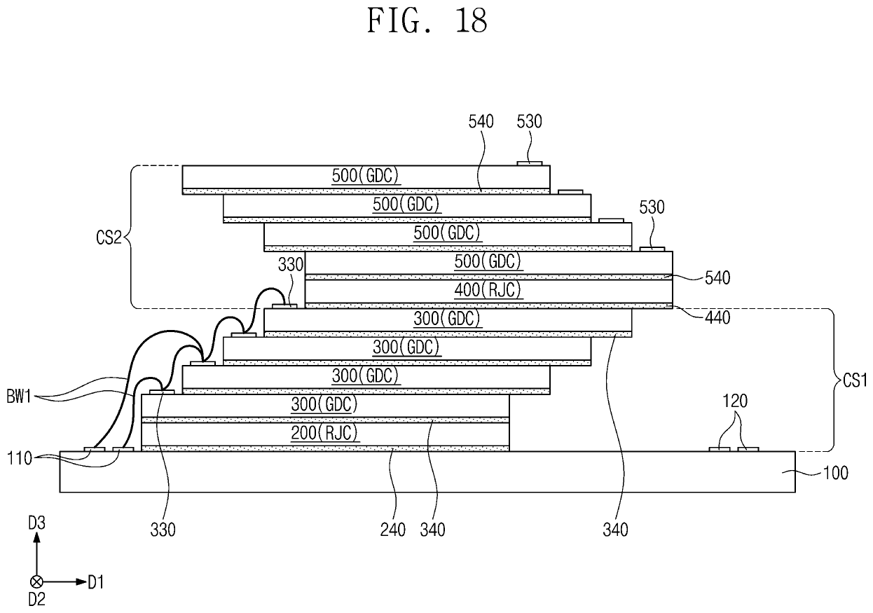

Referring to FIG. 18, the third adhesive member 450 and the fourth adhesive members 550 may be cured to form a third adhesive layer 440 and fourth adhesive layers 540. The curing of the third adhesive member 450 and the fourth adhesive members 550 may be performed at the same time in a single process. For example, the curing process may include an annealing process or a thermal compression process. The curing of the third adhesive member 450 and the fourth adhesive members 550 may cause the third semiconductor chip 400 to be rigidly attached to the first chip stack CS1 and the fourth semiconductor chips 500 to be rigidly attached to the third semiconductor chip 400 or another fourth semiconductor chip 500. Through the processes mentioned above, a second chip stack CS2 may be formed.

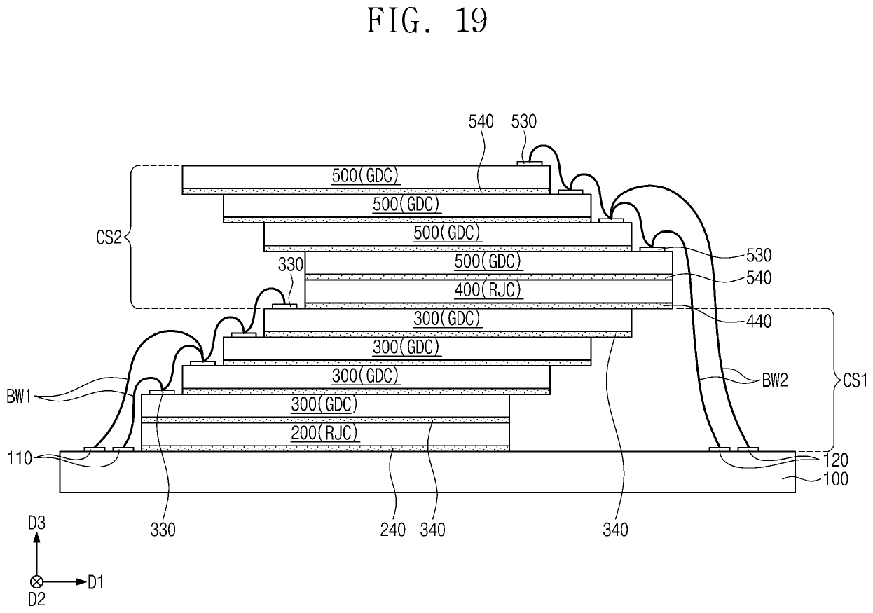

Referring to FIG. 19, the fourth semiconductor chips 500 may be wire-bonded to the package substrate 100. For example, a capillary may be provided on one of the second chip pads 530 of the fourth semiconductor chips 500. The capillary may melt a wire introduced therein to thereby form a ball at a bottom end of the capillary. The capillary may move onto the one second chip pad 530 to allow the ball to be attached to the one second chip pad 530. The capillary may move onto one of the second signal pads 120 or one of the second chip pads 530 of an adjacent another fourth semiconductor chip 500. In this step, a wire released from the capillary may form a wire loop. The capillary may form a ball attached to the one second signal pad 120 at one end of the wire loop. Therefore, second connection wires BW2 may be formed which connect the second chip pads 530 to each other or connect the second chip pads 530 to the second signal pads 120.

Referring back to FIG. 1, a molding layer 600 may be formed on the package substrate 100. For example, a molding member may be coated on the package substrate 100 to cover or overlap the top surface of the package substrate 100, the first chip stack CS1, and the second chip stack CS2. The molding member may be cured to form the molding layer 600.

External terminals 105 may be formed on a bottom surface of the package substrate 100. The external terminals 105 may include a solder ball or a solder pad.

In a semiconductor package according to some embodiments of the present disclosure, as a large thickness is given to a support structure formed of a lowermost second semiconductor chip and a first semiconductor chip, even though a large number of semiconductor chips are provided on a first chip stack and a second chip stack, the semiconductor chips may be firmly supported on the support structure. As a result, the semiconductor package may have increased structural stability.

In a method of fabricating a semiconductor package according to some embodiments of the present disclosure, a single semiconductor wafer may be used to form not only a first semiconductor chip for supporting a first chip stack, but also second semiconductor chips stacked on the first semiconductor chip. As the first and second semiconductor chips can be selected from one semiconductor wafer, the first and second semiconductor chips may be successively stacked and attached. When the first and second semiconductor chips are stacked and attached, there may be no need for replacement of the semiconductor wafer. Therefore, after the first semiconductor chip is attached to a package substrate, the same semiconductor wafer may be used to successively attach the second semiconductor chips to the first semiconductor chip. In addition, in a subsequent process, a first adhesive member and a second adhesive member may be cured simultaneously with each other. It may thus be possible to provide a method of fabricating a semiconductor package whose fabrication process is simplified and process time is reduced.

Although the present disclosure have been described in connection with some embodiments of the present disclosure illustrated in the accompanying drawings, it will be understood by one of ordinary skill in the art that variations in form and detail may be made therein without departing from the spirit and essential feature of the present disclosure. The above disclosed embodiments should thus be considered illustrative and not restrictive.

What is claimed is:

1. A semiconductor package, comprising:
a package substrate; and
a first chip stack on the package substrate,
wherein the first chip stack comprises:
a first semiconductor chip on the package substrate;
a plurality of second semiconductor chips that are on the first semiconductor chip and have an offset stack structure; and
a plurality of first adhesive layers that are respectively on a bottom surface of the first semiconductor chip and bottom surfaces of the second semiconductor chips,
wherein the first semiconductor chip comprises:
a first semiconductor substrate;
a plurality of first integrated elements on a top surface of the first semiconductor substrate; and
a first wiring layer on the top surface of the first semiconductor substrate,
wherein a width of the first semiconductor chip and a width of a lowermost one of the second semiconductor chips are the same, and
wherein the first semiconductor chip is electrically insulated from the package substrate and the second semiconductor chips.

2. The semiconductor package of claim 1, wherein the first semiconductor chip and the second semiconductor chips are a same type.

3. The semiconductor package of claim 1, wherein an entirety of the first semiconductor chip vertically overlaps the lowermost one of the second semiconductor chips.

4. The semiconductor package of claim 1, wherein a first thickness of the first semiconductor chip is the same as a second thickness of each of the second semiconductor chips.

5. The semiconductor package of claim 1, wherein a first thickness of the first semiconductor chip and a second thickness of each of the second semiconductor chips are in a range of about 30 micrometers to about 100 micrometers.

6. The semiconductor package of claim 1, further comprising a plurality of bonding wires that electrically connect the second semiconductor chips to the package substrate,
wherein each of the second semiconductor chips comprises:
a second semiconductor substrate;
a plurality of second integrated elements on a top surface of the second semiconductor substrate; and
a second wiring layer on the top surface of the second semiconductor substrate,
wherein the bonding wires electrically connect one of the second semiconductor chips to the package substrate or electrically connect two of the second semiconductor chips to each other.

7. The semiconductor package of claim 1, wherein a thickness of each of the first adhesive layers is in a range of about 5 micrometers to about 20 micrometers.

8. The semiconductor package of claim 1, wherein the first chip stack further comprises a third semiconductor chip between the first semiconductor chip and the lowermost one of the second semiconductor chips,
wherein the first semiconductor chip, the second semiconductor chips, and the third semiconductor chip are a same type, and
wherein the first semiconductor chip and the third semiconductor chip are vertically aligned with the lowermost one of the second semiconductor chips.

9. The semiconductor package of claim 8, wherein the third semiconductor chip is electrically insulated from the package substrate, the first semiconductor chip and the second semiconductor chips.

10. The semiconductor package of claim 1, further comprising a second chip stack on the first chip stack,
wherein the second chip stack includes:
a fourth semiconductor chip on the first chip stack;
a plurality of fifth semiconductor chips that are on the fourth semiconductor chip and have the offset stack structure; and
a plurality of second adhesive layers that are respectively on a bottom surface of the fourth semiconductor chip and bottom surfaces of the fifth semiconductor chips,
wherein the fourth semiconductor chip and the fifth semiconductor chips are a same type,
wherein the fourth semiconductor chip is vertically aligned with a lowermost one of the fifth semiconductor chips, and
wherein the fourth semiconductor chip is electrically insulated from the package substrate, the first semiconductor chip, the second semiconductor chips, and the fifth semiconductor chips.

11. A semiconductor package, comprising:
a package substrate;
a first chip stack on the package substrate and comprising a plurality of first semiconductor chips that have an offset stack structure;
a second semiconductor chip between the package substrate and the first chip stack;
a plurality of bonding wires that electrically connect the first semiconductor chips to the package substrate;
a molding layer that is on the package substrate, the second semiconductor chip, and the first chip stack; and
a plurality of external terminals on a bottom surface of the package substrate,
wherein the first semiconductor chips and the second semiconductor chip are a same type,
wherein the second semiconductor chip is vertically aligned with a lowermost one of the first semiconductor chips, and
wherein each thickness of the first semiconductor chips is the same as a thickness of the second semiconductor chip.

12. The semiconductor package of claim 11, wherein the second semiconductor chip is electrically insulated from the package substrate and the first semiconductor chips.

13. The semiconductor package of claim 11, wherein each of the first semiconductor chips and the second semiconductor chip comprises:
a semiconductor substrate;
a plurality of integrated elements on a top surface of the semiconductor substrate; and
a wiring layer on the top surface of the semiconductor substrate,
wherein the bonding wires electrically connect the wiring layers of neighboring first semiconductor chips from among the first semiconductor chips to each other or electrically connect the package substrate to the wiring layer of one of the first semiconductor chips.

14. The semiconductor package of claim 11, wherein the second semiconductor chip has a width that is the same as a width of the lowermost one of the first semiconductor chips.

15. The semiconductor package of claim 11, wherein each thickness of the first semiconductor chips and the thickness of the second semiconductor chip are in a range of about 30 micrometers to about 100 micrometers.

16. The semiconductor package of claim 11, further comprising a plurality of adhesive layers that are respectively on a bottom surface of the second semiconductor chip and bottom surfaces of the first semiconductor chips, wherein a thickness of each of the adhesive layers is in a range of about 5 micrometers to about 20 micrometers.

17. The semiconductor package of claim 11, further comprising:
a second chip stack that is on the package substrate and comprises a plurality of third semiconductor chips that have the offset stack structure; and
a fourth semiconductor chip between the first chip stack and the second chip stack,
wherein the third semiconductor chips and the fourth semiconductor chip are a same type,
wherein the fourth semiconductor chip is vertically aligned with a lowermost one of the third semiconductor chips,
wherein a thickness of each of the third semiconductor chips is the same as a thickness of the fourth semiconductor chip, and
wherein the fourth semiconductor chip is electrically insulated from the package substrate, the first semiconductor chips, the second semiconductor chip, and the third semiconductor chips.

18. A semiconductor package, comprising:
a package substrate; and
a first chip stack on the package substrate,
wherein the first chip stack comprises:
a first semiconductor chip on the package substrate;
a plurality of second semiconductor chips that are on the first semiconductor chip and have an offset stack structure; and
a plurality of first adhesive layers that are respectively on a bottom surface of the first semiconductor chip and bottom surfaces of the second semiconductor chips,
wherein the first semiconductor chip comprises:
a first semiconductor substrate;
a plurality of first integrated elements on a top surface of the first semiconductor substrate; and
a first wiring layer on the top surface of the first semiconductor substrate,
wherein a width of the first semiconductor chip and a width of a lowermost one of the second semiconductor chips are the same,
wherein a planar area of the first semiconductor chip and a planar area of the lowermost one of the second semiconductor chips are the same,
wherein a thickness of the first semiconductor chip and a thickness of the lowermost one of the second semiconductor chips are the same,
wherein a thickness of each of the plurality of first adhesive layers is the same, and
wherein the first semiconductor chip is electrically insulated from the package substrate and the second semiconductor chips.

19. The semiconductor package of claim 18, wherein:
the first chip stack further comprises a third semiconductor chip between the first semiconductor chip and the lowermost one of the second semiconductor chips, and
the third semiconductor chip is electrically insulated from the package substrate, the first semiconductor chip, and the second semiconductor chips.

20. The semiconductor package of claim 18, further comprising a second chip stack on the first chip stack,
wherein the second chip stack includes:
a fourth semiconductor chip on the first chip stack;
a plurality of fifth semiconductor chips that are on the fourth semiconductor chip and have the offset stack structure; and
a plurality of second adhesive layers that are respectively on a bottom surface of the fourth semiconductor chip and bottom surfaces of the fifth semiconductor chips,
wherein a width of the fourth semiconductor chip and a width of a lowermost one of the fifth semiconductor chips are the same,
wherein a planar area of the fourth semiconductor chip and a planar area of the lowermost one of the fifth semiconductor chips are the same,
wherein a thickness of the fourth semiconductor chip and a thickness of the lowermost one of the fifth semiconductor chips are the same,
wherein a thickness of each of the plurality of second adhesive layers is the same, and
wherein the fourth semiconductor chip is electrically insulated from the package substrate, the first semiconductor chip, the second semiconductor chips, and the fifth semiconductor chips.
